(19) United States
(12) Patent Application Publication
(10) Pub. No.: US 2024/0088851 A1
(43) Pub. Date: Mar. 14, 2024

(54) DETECTION CIRCUIT, RECEPTION CIRCUIT, AND SEMICONDUCTOR INTEGRATED CIRCUIT

(71) Applicant: Socionext Inc., Kanagawa (JP)

(72) Inventors: Ryoichiro NAKAMURA, Kanagawa (JP); Hideki KANO, Kanagawa (JP)

(21) Appl. No.: 18/519,947

(22) Filed: Nov. 27, 2023

Related U.S. Application Data
(63) Continuation of application No. PCT/JP2021/020377, filed on May 28, 2021.

(51) Int. Cl. H03F 3/45; H03F 1/32

(52) U.S. Cl. CPC H03F 3/45183; H03F 1/3211; H03F 3/45273; H03F 2200/261

(57) ABSTRACT

A detection circuit includes: a differential input circuit configured to receive differential input voltages and generate first differential detection currents corresponding to the differential input voltages; a detection current generation circuit configured to form a current mirror circuit with the differential input circuit and generate second differential detection currents corresponding to the first differential detection currents; a detection voltage generation circuit configured to receive the second differential detection currents and generate a detection voltage having a voltage corresponding to the second differential detection currents; and a comparator circuit configured to compare the detection voltage and a reference voltage and output a signal indicating whether or not the differential input voltages are in a voltage state representing a given idle mode.

### CROSS-REFERENCE TO RELATED APPLICATION

This application is a continuation application of International Application PCT/JP2021/020377 filed on May 28, 2021, and designated the U.S., the entire contents of which are incorporated herein by reference.

### FIELD

The embodiment discussed herein is directed to a detection circuit, a reception circuit, and a semiconductor integrated circuit.

### BACKGROUND

Patent Document 1 has described an optical signal detection circuit that detects the presence or absence of input of an optical signal based on differential signals obtained by photoelectric conversion of an optical signal. A differential amplifier circuit differentially amplifies the differential signals input via coupling capacitors and outputs the amplified differential signals as an amplified output signal. A differential current adding circuit adds a direct current corresponding to an input offset adjustment voltage to a positive phase signal and a negative phase signal of the amplified output signal, thereby adjusting direct-current offset voltages of the positive phase signal and the negative phase signal and outputting them as a current-added output signal. A comparator compares voltage values of a positive phase signal and a negative phase signal of the current-added output signal, and outputs the comparison result as a comparison output signal. A holding circuit rectifies the comparison output signal, charges it in a holding capacitor, and discharges a direct-current holding voltage obtained by charging in a discharge resistor. A hysteresis comparator circuit compares the holding voltage with two determination threshold voltages, which are different from each other, determined by an input sensitivity adjustment voltage, and outputs the comparison result as an optical signal detection signal indicating the presence or absence of input of an optical signal.

Non-Patent Document 1 has described an electrical idle detector that detects an electrical idle (EI) signal using a peak detector including a source follower.
[Patent Document 1] Japanese Laid-open Patent Publication No. 2013-255056
[Non-Patent Document 1] Nawathe et al., “Implementation of an 8-Core, 64-Thread, Power-Efficient SPARC Server on a Chip”, IEEE JOURNAL OF SOLID-STATE CIRCUITS, VOL. 43, NO. 1, JANUARY 2008

Patent Document 1 uses a differential amplifier circuit. The differential amplifier circuit needs operation at a high power supply voltage, to thereby cause an increase in power consumption, and needs to use large-sized transistors, to thereby cause an increase in circuit area.

Non-Patent Document 1 uses a source follower. The source follower has a voltage gain of 1 or less, and thus the signal is attenuated. Therefore, the source follower needs a high voltage gain, to thereby cause an increase in power consumption, and needs to use large-sized transistors, to thereby cause an increase in circuit area.

### SUMMARY

A detection circuit includes: a differential input circuit configured to receive differential input voltages and generate first differential detection currents corresponding to the differential input voltages; a detection current generation circuit configured to form a current mirror circuit with the differential input circuit and generate second differential detection currents corresponding to the first differential detection currents; a detection voltage generation circuit configured to receive the second differential detection currents and generate a detection voltage having a voltage corresponding to the second differential detection currents; and a comparator circuit configured to compare the detection voltage and a reference voltage and output a signal indicating whether or not the differential input voltages are in a voltage state representing a given idle mode.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 is a block diagram illustrating a configuration example of a semiconductor integrated circuit according to this embodiment;

FIG. 2 is a circuit diagram illustrating a configuration example of a detection circuit;

FIG. 3 is a view illustrating an example of a voltage waveform for explaining the operation of the detection circuit;

FIG. 4 is a view illustrating an example of a simulation result of a voltage waveform; and

FIG. 5 is a view illustrating an example of a simulation result of a voltage waveform.

### DESCRIPTION OF EMBODIMENTS

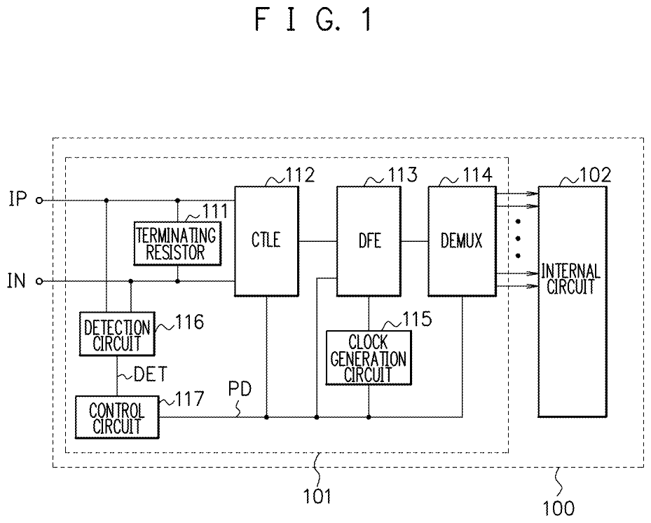

FIG. 1 is a block diagram illustrating a configuration example of a semiconductor integrated circuit 100 according to this embodiment. The semiconductor integrated circuit 100 includes a reception circuit 101 and an internal circuit 102. The reception circuit 101 receives differential input voltages IP and IN and outputs reception data to the internal circuit 102. The internal circuit 102 processes the reception data.

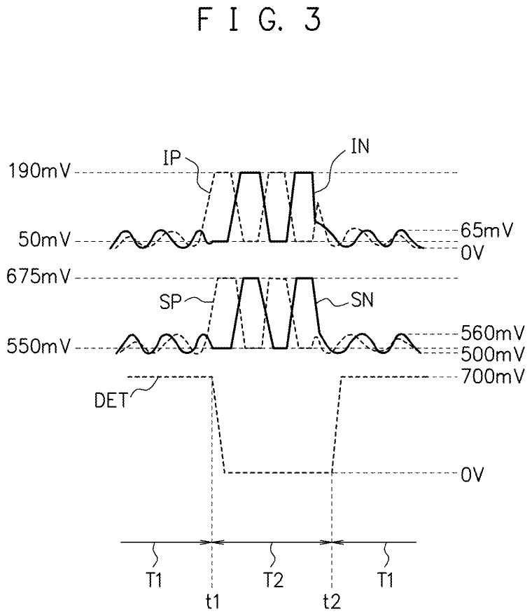

The reception circuit 101 receives the input voltages IP and IN. The input voltages IP and IN are differential input voltages. As illustrated in FIG. 3, during an active mode period T2, the input voltages IP and IN are differential input voltages representing a data signal, one of which is at a high level and the other is at a low level. During an electrical idle (EI) mode period T1, the input voltages IP and IN represent an electrical idle (EI) signal and both are at a substantially low level. Hereinafter, the electrical idle (EI) is simply referred to as idle.

The reception circuit 101 includes a terminating resistor 111, a continuous time linear equalizer (CTLE) 112, a decision feedback equalizer (DFE) 113, a demultiplexer circuit (DEMUX) 114, a clock generation circuit 115, a detection circuit 116, and a control circuit 117.

The terminating resistor 111 is connected between transmission lines of the input voltages IP and IN. The continuous time linear equalizer 112 reduces intersymbol interference jitter (ISI jitter) of the received differential input voltages IP and IN. The clock generation circuit 115 generates a clock signal. The decision feedback equalizer 113 decides and equalizes a differential input voltage output from the continuous time linear equalizer 112 in synchronization with the clock signal generated by the clock generation circuit, and outputs reception data. The demultiplexer circuit 114 converts the reception data output from the decision feedback equalizer 113 from serial data to parallel data and outputs the parallel reception data to the internal circuit 102.

The detection circuit 116 receives the received differential input voltages IP and IN, and outputs a detection signal DET indicating whether or not the differential input voltages IP and IN are in a voltage state representing a predetermined idle mode. As illustrated in FIG. 3, during the idle mode period T1, the detection signal DET goes to a high level. During the active mode period T2, the detection signal DET goes to a low level.

When the high-level detection signal DET indicating that the differential input voltages IP and IN are in a voltage state representing a predetermined idle mode is output, the control circuit 117 controls the continuous time linear equalizer 112, the decision feedback equalizer 113, the demultiplexer circuit 114, and the clock generation circuit 115 to be turned off according to a high level of a power-down signal PD. When receiving the high-level power-down signal PD, for example, the continuous time linear equalizer 112, the decision feedback equalizer 113, the demultiplexer circuit 114, and the clock generation circuit 115 are each disconnected from at least one of a power supply potential node and a reference potential node by a switching transistor. Thereby, in the idle mode, the reception circuit 101 can reduce power consumption.

Further, when the low-level detection signal DET indicating that the differential input voltages IP and IN are not in a voltage state representing a predetermined idle mode is output, the control circuit 117 controls the continuous time linear equalizer 112, the decision feedback equalizer 113, the demultiplexer circuit 114, and the clock generation circuit 115 to be turned on according to a low level of the power-down signal PD. When receiving the low-level power-down signal PD, for example, the continuous time linear equalizer 112, the decision feedback equalizer 113, the demultiplexer circuit 114, and the clock generation circuit 115 are each connected to the power supply potential node and the reference potential node by the switching transistor. Thereby, in the active mode, the reception circuit 101 becomes operable.

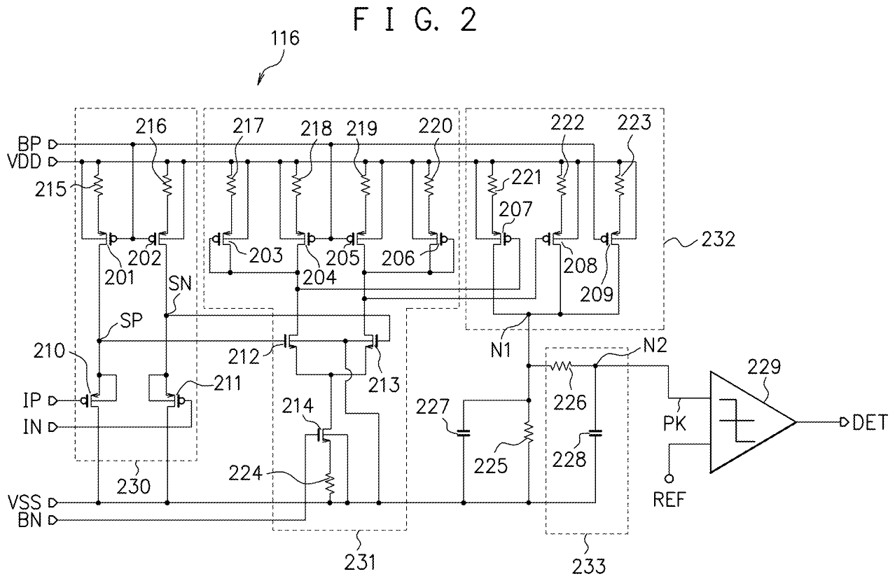

FIG. 2 is a circuit diagram illustrating a configuration example of the detection circuit 116 in FIG. 1. The detection circuit 116 includes p-channel field-effect transistors 201 to 211, n-channel field-effect transistors 212 to 214, resistors 215 to 226, capacitors 227 to 228, and a comparator circuit 229.

A power supply potential node VDD is, for example, a 0.8-V power supply potential node. A reference potential node VSS is, for example, a 0-V ground node. Bias potential nodes BP and BN each are a bias potential node. Input voltages IP and IN are the same as the input voltages IP and IN in FIG. 1, respectively.

The resistor 215 is connected between the power supply potential node VDD and a source of the p-channel field-effect transistor 201. The p-channel field-effect transistor 201 has a gate thereof connected to the bias potential node BP and has a drain thereof connected to a source of the p-channel field-effect transistor 210. The p-channel field-effect transistor 210 has a gate thereof connected to a node of the input voltage IP and has a drain thereof connected to the reference potential node VSS.

The resistor 216 is connected between the power supply potential node VDD and a source of the p-channel field-effect transistor 202. The p-channel field-effect transistor 202 has a gate thereof connected to the bias potential node BP and has a drain thereof connected to a source of the p-channel field-effect transistor 211. The p-channel field-effect transistor 211 has a gate thereof connected to a node of the input voltage IN and has a drain thereof connected to the reference potential node VSS.

The resistor 217 is connected between the power supply potential node VDD and a source of the p-channel field-effect transistor 203. The p-channel field-effect transistor 203 has a gate thereof and a drain thereof connected to a drain of the n-channel field-effect transistor 212.

The resistor 218 is connected between the power supply potential node VDD and a source of the p-channel field-effect transistor 204. The p-channel field-effect transistor 204 has a gate thereof connected to the bias potential node BP and has a drain thereof connected to the drain of the n-channel field-effect transistor 212.

The resistor 219 is connected between the power supply potential node VDD and a source of the p-channel field-effect transistor 205. The p-channel field-effect transistor 205 has a gate thereof connected to the bias potential node BP and has a drain thereof connected to a drain of the n-channel field-effect transistor 213.

The resistor 220 is connected between the power supply potential node VDD and a source of the p-channel field-effect transistor 206. The p-channel field-effect transistor 206 has a gate thereof and a drain thereof connected to the drain of the n-channel field-effect transistor 213.

The n-channel field-effect transistor 212 has a gate thereof connected to the source of the p-channel field-effect transistor 210 and has a source thereof connected to a drain of the n-channel field-effect transistor 214.

The n-channel field-effect transistor 213 has a gate thereof connected to the source of the p-channel field-effect transistor 211 and has a source thereof connected to the drain of the n-channel field-effect transistor 214.

The n-channel field-effect transistor 214 has a gate thereof connected to the bias potential node BN. The resistor 224 is connected between a source of the n-channel field-effect transistor 214 and the reference potential node VSS.

The resistor 221 is connected between the power supply potential node VDD and a source of the p-channel field-effect transistor 207. The p-channel field-effect transistor 207 has a gate thereof connected to the drain of the n-channel field-effect transistor 212 and has a drain thereof connected to a node N1.

The resistor 222 is connected between the power supply potential node VDD and a source of the p-channel field-effect transistor 208. The p-channel field-effect transistor 208 has a gate thereof connected to the drain of the n-channel field-effect transistor 213 and has a drain thereof connected to the node N1.

The resistor 223 is connected between the power supply potential node VDD and a source of the p-channel field-effect transistor 209. The p-channel field-effect transistor 209 has a gate thereof connected to the bias potential node BP and has a drain thereof connected to the node N1.

The capacitor 227 is connected between the node N1 and the reference potential node VSS. The resistor 225 is connected between the node N1 and the reference potential node VSS. The resistor 226 is connected between the node N1 and a node N2. The capacitor 228 is connected between the node N2 and the reference potential node VSS.

A detection voltage PK is the voltage of the node N2. The comparator circuit 229 compares the detection voltage PK and a reference voltage REF and outputs a detection signal DET. The detection signal DET is a signal indicating whether or not the differential input voltages IP and IN are in a voltage state representing a predetermined idle mode.

The detection circuit 116 includes a level shift circuit 230, a differential pair circuit 231, a peak detection circuit 232, and a low-pass filter circuit 233. The level shift circuit 230 includes the p-channel field-effect transistors 201, 202, 210, and 211 and the resistors 215 and 216. The p-channel field-effect transistors 201 and 202 each are a constant current source. A voltage SP is the voltage of the gate of the n-channel field-effect transistor 212. A voltage SN is the voltage of the gate of the n-channel field-effect transistor 213. The voltages SP and SN are differential voltages.

FIG. 3 is a view illustrating an example of a voltage waveform for explaining the operation of the detection circuit 116 in FIG. 2. Before a time t1, the operation is in the idle mode period T1. Between the time t1 and a time t2, the operation is in the active mode period T2. After the time t2, the operation is in the idle mode period. During the active mode period T2, the input voltages IP and IN are differential input voltages representing a data signal, one of which is at a high level and the other is at a low level. During the idle mode period T1, the input voltages IP and IN represent an idle signal and are both at a substantially low level. The level shift circuit 230 level shifts the differential input voltages IP and IN in the range of 0 V to 190 mV, for example, and outputs the differential voltages SP and SN in the range of 500 mV to 675 mV, for example. The voltage range of the differential voltages SP and SN is the voltage range for the differential pair of n-channel field-effect transistors 212 and 213 operate in an operating region.

The differential pair circuit 231 includes the differential pair of n-channel field-effect transistors 212 and 213, the resistors 217 to 220 and 224, the p-channel field-effect transistors 203 to 206, and the n-channel field-effect transistor 214. The p-channel field-effect transistors 203 and 206 are diode-connected to each other. The p-channel field-effect transistors 204 and 205 each are a constant current source. The gates of the n-channel field-effect transistors 212 and 213 receive the differential voltages SP and SN level shifted by the level shift circuit 230. A current corresponding to the voltage SP flows through the drain of the n-channel field-effect transistor 212. A current corresponding to the voltage SN flows through the drain of the n-channel field-effect transistor 213. Since the voltages SP and SN are differential voltages, differential currents (differential detection currents) flow through the drains of the n-channel field-effect transistors 212 and 213. The differential pair circuit 231 generates the differential detection currents corresponding to the differential voltages SP and SN.

The level shift circuit 230 raises a common mode voltage of the differential input voltages IP and IN to the operating region of the differential pair of n-channel field-effect transistors 212 and 213, and outputs the differential voltages SP and SN. The differential pair of n-channel field-effect transistors 212 and 213 remove the common mode voltage of the differential voltages SP and SN.

The level shift circuit 230 and the differential pair circuit 231 form a differential input circuit, receive the differential input voltages IP and IN, and generate the differential detection currents corresponding to the differential input voltages IP and IN.

The peak detection circuit 232 includes the differential pair of p-channel field-effect transistors 207 and 208, the p-channel field-effect transistor 209, and the resistors 221 to 223. The p-channel field-effect transistor 209 is a constant current source for fine adjustment. The gates of the p-channel field-effect transistors 207 and 208 receive the differential voltages corresponding to the differential currents flowing through the drains of the n-channel field-effect transistors 212 and 213. The p-channel field-effect transistors 203 and 207 form a current mirror circuit whose gates are both connected to the drain of the n-channel field-effect transistor 212, where currents that are the same as or proportional to each other flow. The p-channel field-effect transistors 206 and 208 form a current mirror circuit whose gates are both connected to the drain of the n-channel field-effect transistor 213, where currents that are the same as or proportional to each other flow. The differential currents flow through the drains of the n-channel field-effect transistors 212 and 213, and thus the differential currents (differential detection currents) also flow through the drains of the p-channel field-effect transistors 207 and 208. The current (peak current), which is the sum of the drain currents of the p-channel field-effect transistors 207 and 208, flows through the node N1. The peak detection circuit 232 is a detection current generation circuit and forms a current mirror circuit with the differential pair circuit 231 to generate differential currents (differential detection currents) corresponding to the differential currents flowing through the drains of the n-channel field-effect transistors 212 and 213.

Incidentally, when the differential voltages SP and SN become the common mode voltage, little current flows through the drains of the differential pair of n-channel field-effect transistors 212 and 213. In this case, little current also flows through the drains of the differential pair of p-channel field-effect transistors 207 and 208. Therefore, a minute current always flows through the p-channel field-effect transistor 209, which is a constant current source for non-adjustment.

Tail currents of the differential pair of p-channel field-effect transistors 207 and 208 flow through the resistor 225. The resistor 225 receives the differential currents flowing through the drains of the p-channel field-effect transistors 207 and 208 to generate a voltage corresponding to the differential currents flowing through the drains of the p-channel field-effect transistors 207 and 208. The resistor 225 converts the currents flowing through the node N1 into voltage.

The low-pass filter circuit 233 includes the resistor 226 and the capacitor 228, low-pass filters the voltage of the node N1, and outputs the low-pass filtered detection voltage PK to the node N2. The detection voltage PK is a voltage obtained by reducing a high-frequency component from the voltage of the node N1. The capacitor 227 assists a low-pass filtering function of the low-pass filter circuit 233. Incidentally, the capacitor 227 may be deleted.

The resistor 225 and the low-pass filter circuit 233 form a detection voltage generation circuit, receives the differential currents flowing through the drains of the p-channel field-effect transistors 207 and 208, and generates the detection voltage PK having the voltage corresponding to the differential currents flowing through the drains of the p-channel field-effect transistors 207 and 208.

The comparator circuit 229 compares the detection voltage PK and the reference voltage REF and outputs a detection signal DET indicating whether or not the differential input voltages IP and IN are in a voltage state representing a predetermined idle mode. Specifically, when the detection voltage PK is lower than the reference voltage REF, the comparator circuit 229 outputs a high-level detection signal DET indicating that the differential input voltages IP and IN are in a voltage state representing a predetermined idle mode.

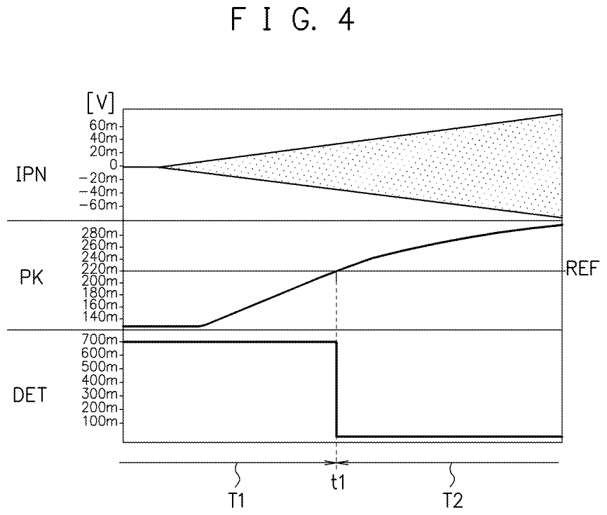

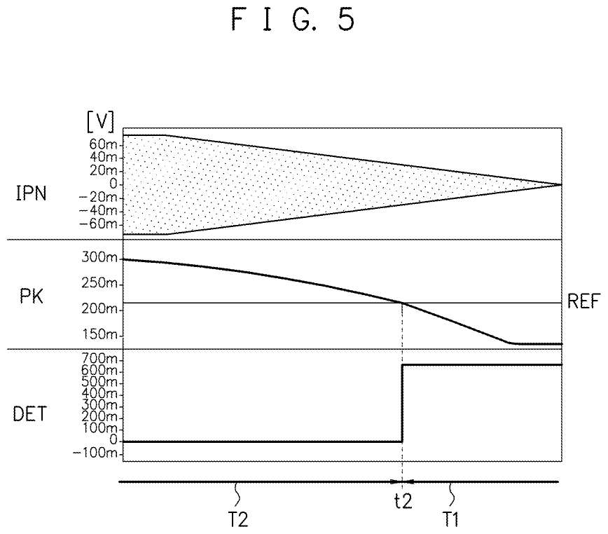

FIG. 4 is a view illustrating an example of a simulation result of a voltage waveform around the time t1 in FIG. 3. FIG. 5 is a view illustrating an example of a simulation result of a voltage waveform around the time t2 in FIG. 3. Before the time t1, the operation is in the idle mode period T1. Between the time t1 and the time t2, the operation is in the active mode period T2. After the time t2, the operation is in the idle mode period T1. A differential input voltage IPN is the voltage of (the input voltage IP)−(the input voltage IN). The detection voltage PK is the voltage of the node N2 in FIG. 2. The detection signal DET is the output signal of the comparator circuit 229 in FIG. 2.

In the stable period during the idle mode period T1 before the time t1 in FIG. 4, the differential input voltage IPN is about 0 V because the input voltages IP and IN are substantially the same as each other as illustrated in FIG. 3. The input voltages IP and IN are both at a low level, and thus the currents flowing through the drains of the differential pair of n-channel field-effect transistors 212 and 213 are both small, and the currents flowing through the drains of the differential pair of p-channel field-effect transistors 207 and 208 are also both small. As a result, the detection voltage PK becomes low. Since the detection voltage PK is lower than the reference voltage REF, the comparator circuit 229 outputs a high-level detection signal DET. During the idle mode period T1, the detection signal DET is at a high level.

Around the time t1 in FIG. 4, the amplitude of the differential input voltage IPN increases gradually. Then, the total current flowing through the drains of the differential pair of n-channel field-effect transistors 212 and 213 increases gradually, and the total current flowing through the drains of the differential pair of p-channel field-effect transistors 207 and 208 also increases gradually. As a result, the detection voltage PK increases gradually. After the time t1, the comparator circuit 229 outputs a low-level detection signal DET because the detection voltage PK is higher than the reference voltage REF. During the active mode period T2, the detection signal DET is at a low level.

Around the time t2 in FIG. 5, the amplitude of the differential input voltage IPN decreases gradually. Then, the total current flowing through the drains of the differential pair of n-channel field-effect transistors 212 and 213 decreases gradually, and the total current flowing through the drains of the differential pair of p-channel field-effect transistors 207 and 208 also decreases gradually. As a result, the detection voltage PK decreases gradually. After the time t2, the comparator circuit 229 outputs a high-level detection signal DET because the detection voltage PK is lower than the reference voltage REF. During the idle mode period T1, the detection signal DET is at a high level.

The low-pass filter circuit 233 is provided, thereby making it possible to reduce noise in which the detection signal DET goes to a high level and a low level alternately repeatedly at a high frequency, around the times t1 and t2.

As above, the detection circuit 116 can output a high-level detection signal DET during the idle mode period T1, and can output a low-level detection signal DET during the active mode period T2. The detection circuit 116 can detect with high accuracy the detection signal DET indicating whether or not the differential input voltages IP and IN are in a voltage state representing the idle mode.

Using a source follower with a high voltage gain, Non-Patent Document 1 needs operation at a high power supply voltage, to thereby cause an increase in power consumption, and needs to use large-sized transistors, to thereby cause an increase in circuit area.

The detection circuit 116 according to this embodiment does not use the source follower with a high voltage gain, but uses a current mirror circuit, thus making it possible to reduce the power supply voltage (for example, 0.8 V) of the power supply potential node VDD, reduce the power consumption, reduce the transistor size, and reduce the circuit area.

Further, since the comparator circuit 229 compares the low-frequency detection voltage DET output from the low-pass filter circuit 233 and the reference voltage REF, there is no need for high-speed operation and the power consumption and the circuit area can be reduced.

Note that the above-described embodiment merely illustrates concrete examples of implementing the present invention, and the technical scope of the present invention is not to be construed in a restrictive manner by the embodiment. That is, the present invention may be implemented in various forms without departing from the technical spirit or main features thereof.

The power consumption and the circuit area can be reduced when detecting the idle mode based on the differential input voltages.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. A detection circuit, comprising:
a differential input circuit configured to receive differential input voltages and generate first differential detection currents corresponding to the differential input voltages;
a detection current generation circuit configured to form a current mirror circuit with the differential input circuit and generate second differential detection currents corresponding to the first differential detection currents;
a detection voltage generation circuit configured to receive the second differential detection currents and generate a detection voltage having a voltage corresponding to the second differential detection currents; and
a comparator circuit configured to compare the detection voltage and a reference voltage and output a signal indicating whether or not the differential input voltages are in a voltage state representing a given idle mode.

2. The detection circuit according to claim 1, wherein
the differential input circuit includes a first differential pair of transistors, the first differential pair of transistors configured to have the first differential detection currents flow therethrough.

3. The detection circuit according to claim 2, wherein
the differential input circuit includes a level shift circuit, the level shift circuit configured to level shift the differential input voltages, and
the first differential pair of transistors are configured to receive differential input voltages level shifted by the level shift circuit.

4. The detection circuit according to claim 1, wherein
the detection current generation circuit includes a second differential pair of transistors, the second differential pair of transistors configured to receive differential voltages corresponding to the first differential detection currents and supply the second differential detection currents.

5. The detection circuit according to claim 4, wherein
the detection voltage generation circuit includes a resistor, the resistor configured to have tail currents of the second differential pair of transistors flow therethrough.

6. The detection circuit according to claim 1, wherein
the detection voltage generation circuit includes a low-pass filter circuit, the low-pass filter circuit configured to low-pass filter the detection voltage.

7. The detection circuit according to claim 1, wherein
the comparator circuit is configured to output a signal indicating that the differential input voltages are in a voltage state representing the given idle mode when the detection voltage is higher than the reference voltage.

8. A reception circuit, comprising:
a continuous time linear equalizer circuit configured to reduce intersymbol interference jitter of received differential input voltages;
a detection circuit configured to receive the received differential input voltages and output a signal indicating whether or not the differential input voltages are in a voltage state representing a given idle mode; and
a control circuit configured to control the continuous time linear equalizer circuit to be turned off when the signal indicating that the differential input voltages are in a voltage state representing the given idle mode is output, wherein
the detection circuit includes:
a differential input circuit configured to receive the differential input voltages and generate first differential detection currents corresponding to the differential input voltages;
a detection current generation circuit configured to form a current mirror circuit with the differential input circuit and generate second differential detection currents corresponding to the first differential detection currents;
a detection voltage generation circuit configured to receive the second differential detection currents and generate a detection voltage having a voltage corresponding to the second differential detection currents; and
a comparator circuit configured to compare the detection voltage and a reference voltage and output a signal indicating whether or not the differential input voltages are in a voltage state representing the given idle mode.

9. The reception circuit according to claim 8 further comprising:
a decision feedback equalizer circuit configured to decide and equalize an input voltage output from the continuous time linear equalizer circuit and output reception data; and
a demultiplexer circuit configured to convert the reception data output from the decision feedback equalizer from serial data to parallel data, wherein
the control circuit is configured to further control the decision feedback equalizer circuit and the demultiplexer circuit to be turned off.

10. The reception circuit according to claim 8, wherein
the differential input circuit includes a first differential pair of transistors, the first differential pair of transistors configured to have the first differential detection currents flow therethrough.

11. The reception circuit according to claim 10, wherein
the differential input circuit includes a level shift circuit, the level shift circuit configured to level shift the differential input voltages, and
the first differential pair of transistors are configured to receive differential input voltages level shifted by the level shift circuit.

12. The reception circuit according to claim 8, wherein
the detection current generation circuit includes a second differential pair of transistors, the second differential pair of transistors configured to receive differential voltages corresponding to the first differential detection currents and supply the second differential detection currents.

13. The reception circuit according to claim 8, wherein
the comparator circuit is configured to output a signal indicating that the differential input voltages are in a voltage state representing the given idle mode when the detection voltage is higher than the reference voltage.

14. A semiconductor integrated circuit, comprising:
a reception circuit configured to receive differential input voltages and output reception data; and
an internal circuit configured to process the reception data, wherein
the reception circuit includes:
a continuous time linear equalizer circuit configured to reduce intersymbol interference jitter of the received differential input voltages;
a detection circuit configured to receive the received differential input voltages and output a signal indicating whether or not the differential input voltages are in a voltage state representing a given idle mode; and
a control circuit configured to control the continuous time linear equalizer circuit to be turned off when the signal indicating that the differential input voltages are in a voltage state representing a predetermined idle mode is output,
the detection circuit includes:
a differential input circuit configured to receive the differential input voltages and generate first differential detection currents corresponding to the differential input voltages;
a detection current generation circuit configured to form a current mirror circuit with the differential input circuit and generate second differential detection currents corresponding to the first differential detection currents;
a detection voltage generation circuit configured to receive the second differential detection currents and generate a detection voltage having a voltage corresponding to the second differential detection currents; and
a comparator circuit configured to compare the detection voltage and a reference voltage and output a signal indicating whether or not the differential input voltages are in a voltage state representing the given idle mode.

15. The semiconductor integrated circuit according to claim 14, further comprising:
a decision feedback equalizer circuit configured to decide and equalize an input voltage output from the continuous time linear equalizer circuit and output reception data; and
a demultiplexer circuit configured to convert the reception data output from the decision feedback equalizer from serial data to parallel data, wherein
the control circuit is configured to further control the decision feedback equalizer circuit and the demultiplexer circuit to be turned off.

16. The semiconductor integrated circuit according to claim 14, wherein
the differential input circuit includes a first differential pair of transistors, the first differential pair of transistors configured to have the first differential detection currents flow therethrough.

17. The semiconductor integrated circuit according to claim 16, wherein
the differential input circuit includes a level shift circuit, the level shift circuit configured to level shift the differential input voltages, and
the first differential pair of transistors are configured to receive differential input voltages level shifted by the level shift circuit.

18. The semiconductor integrated circuit according to claim 14, wherein
the detection current generation circuit includes a second differential pair of transistors, the second differential pair of transistors configured to receive differential voltages corresponding to the first differential detection currents and supply the second differential detection currents.

19. The semiconductor integrated circuit according to claim 14, wherein
the comparator circuit is configured to output a signal indicating that the differential input voltages are in a voltage state representing the given idle mode when the detection voltage is higher than the reference voltage.
